(19) United States
(12) Patent Application Publication
(10) Pub. No.: US 2026/0305080 A1
(43) Pub. Date: Oct. 1, 2026

(54) DISPLAY DEVICE

(71) Applicant: LG DISPLAY CO., LTD., SEOUL (KR)

(72) Inventors: HongMan Moon, Goyuang-si (KR); Keongjin Lee, Seoul (KR); SeongWook Choi, Gumi-si (KR); JooBong Hyun, Seoul (KR)

(21) Appl. No.: 19/429,908

(22) Filed: Dec. 22, 2025

(30) Foreign Application Priority Data
Mar. 31, 2025 (KR) 10-2025-0041606

(51) Int. Cl. H10K 59/122; H10K 59/124

(52) U.S. Cl. CPC H10K 59/122; H10K 59/124

(57) ABSTRACT

A display device includes a substrate, a first planarization layer disposed on the substrate and including a convex portion and a concave portion, an island pattern disposed on the concave portion of the first planarization layer, a light emitting element including (i) a lower electrode disposed on a side surface of the island pattern and on a top surface of the island pattern, (ii) a light emitting layer disposed on the lower electrode, and (iii) an upper electrode disposed on the light emitting layer, a bank disposed, in a cross-section view, between the first electrode and the light emitting layer on the first planarization layer and surrounding a lower portion of the island pattern in a plan view, and an optical member disposed on the light emitting element and disposed to overlap the island pattern.

### CROSS-REFERENCE TO RELATED APPLICATIONS

Pursuant to 35 U.S.C. § 119(a), this application claims the benefit of an earlier filing date and right of priority to Korean Patent Application No. 10-2025-0041606 filed on Mar. 31, 2025, in the Ministry of Intellectual Property of the Republic of Korea, the disclosure of which is incorporated herein by reference in its entirety.

### TECHNICAL FIELD

The present disclosure relates to a display device.

### BACKGROUND

With the development of technologies in modern society, display devices are being used in various ways to provide information to users. For example, display devices are implemented in electronic signs that simply transmit visual information in one direction, as well as various electronic devices that utilize more complex technology to determine a user's input and provide information in response to the user's input.

### SUMMARY

A display device according to an example implementation of the present disclosure includes: a substrate; a first planarization layer disposed on the substrate and including a convex portion and a concave portion; an island pattern disposed on the concave portion of the first planarization layer, a light emitting element including (i) a first electrode disposed on a side surface of the island pattern and on a top surface of the island pattern; (ii) a light emitting layer disposed on the first electrode; and (iii) a second electrode disposed on the light emitting layer; a bank disposed, in a cross-section view, between the first electrode and the light emitting layer on the first planarization layer and disposed, in a plan view, to surround a lower portion of the island pattern; and an optical member disposed on the light emitting element and disposed to overlap the island pattern.

A display device according to another example implementation of the present disclosure includes a substrate, a first planarization layer disposed on the substrate, a first island pattern disposed on the first planarization layer, a plurality of first light emitting elements including a first emission area disposed on a top surface of the island pattern and on a side surface of the first island pattern, and a circular first optical member overlapping the first emission area.

Other detailed matters of the implementations are included in the detailed description and the drawings. Implementations disclosed herein can provide various technical effects, some examples of which are described below.

According to the present disclosure, it is possible to reduce deterioration in luminance that may occur outside the emission area as the light emitting element deteriorates.

According to the present disclosure, it is possible to mitigate an afterimage from being visually recognized due to a luminance difference between a light emitting element deteriorated at a peripheral viewing angle and a light emitting element which is not deteriorated while the emission area is reduced.

According to the present disclosure, it is possible to improve the lifespan of the display device by mitigating a potential defect caused by the contraction of the light emitting area and to drive the display device with low power in terms of reducing production energy.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an example view of a display device according to an example implementation of the present disclosure.

FIG. 2 is a functional block diagram of a display device according to an example implementation of the present disclosure.

FIG. 3 is a circuit diagram illustrating an example of a display device according to an example implementation of the present disclosure.

FIG. 4 is an enlarged plan view illustrating an arrangement of a display device according to an example implementation of the present disclosure.

FIG. 5 is a cross-sectional view of the display device of FIG. 4 taken along line A-A′.

FIG. 6 is a cross-sectional view of the display device of FIG. 4 taken along line B-B′.

FIG. 7 is a cross-sectional view of a display device of FIG. 4 taken in an area adjacent to a non-display area.

FIG. 8A is a result of simulating a difference in luminance before and after deterioration of a light emitting element in a comparative example and an example.

FIG. 8B is a simulation result showing a ratio of a difference in luminance before and after deterioration of a light emitting element in a comparative example and an example.

FIG. 9 is a cross-sectional view of a display device according to another example implementation of the present disclosure.

### DETAILED DESCRIPTION

A display device can be implemented in a vehicle to provide various information to a driver and a passenger of the vehicle. However, a display device implemented in a vehicle is often constrained to display content appropriately so as not to interfere with the operation of the vehicle. For example, the display device is typically constrained in displaying content that may interfere with the concentration of a driver driving while the vehicle is in operation.

Implementations of the present disclosure can provide a display device capable of reducing deterioration in luminance caused by deterioration of a light emitting element.

Implementations of the present disclosure can provide a display device that can suppress deterioration in luminance which may occur at an outer portion of an emission area while an emission area is reduced due to deterioration of the light emitting element.

Implementations of the present disclosure can provide a display device that can suppress a phenomenon in which an afterimage is visually recognized due to a luminance difference between a light emitting element deteriorated at a peripheral viewing angle and a light emitting element which is not deteriorated, in scenarios where an emission area is reduced.

Implementations of the present disclosure can provide a display device capable of improving a lifespan of the display device and low-power driving in terms of reducing production energy by minimizing a potential defect caused by contraction of a light emitting area.

Objects of the present disclosure are not limited to the above-mentioned objects, and other objects, which are not mentioned above, can be clearly understood by those skilled in the art from the following descriptions.

Advantages and characteristics of the present disclosure and a method of achieving the advantages and characteristics will be clear by referring to example implementations described below in detail together with the accompanying drawings. However, the present disclosure is not limited to the example implementations disclosed herein but will be implemented in various forms. The example implementations are provided by way of example only so that those skilled in the art can fully understand the disclosures of the present disclosure and the scope of the present disclosure.

The shapes, sizes, ratios, angles, numbers, and the like illustrated in the accompanying drawings for describing the example implementations of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, the element or layer may be disposed directly on the another element or layer, or another element or layer may be interposed therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various implementations of the present disclosure can be partially or entirely adhered to or combined with each other and can be interlocked and operated in technically various ways, and the implementations can be carried out independently of or in association with each other.

Hereinafter, example implementations of the present disclosure will be described in detail with reference to accompanying drawings.

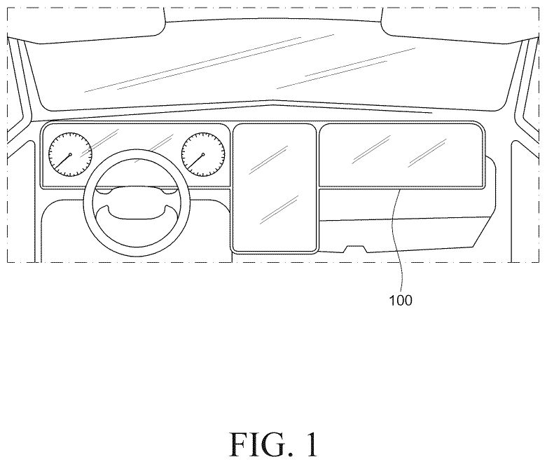

FIG. 1 is an example view of a display device according to an example implementation of the present disclosure.

Referring to FIG. 1, a display device 100 may be disposed on at least a part of a dashboard of a vehicle. The dashboard of the vehicle may include a configuration disposed in front of front seats (e.g., driver's seat and passenger seat) of the vehicle. For example, an input configuration for manipulating various functions (e.g., an air conditioner, an audio system, and a navigation system) inside the vehicle may be disposed on the dashboard of the vehicle.

The display device 100 may be disposed on the dashboard of the vehicle and operate as an input unit for manipulating at least some of various functions of the vehicle. The display device 100 may provide various information related to the vehicle, for example, driving information of the vehicle (for example, a current speed of the vehicle, a remaining fuel amount, and a driving distance), information on parts of the vehicle (for example, a damage degree of a vehicle tire), and the like.

The display device 100 may be disposed across the driver seat and the passenger seat disposed in the front seats of the vehicle. The user of the display device 100 may include a driver of the vehicle and a passenger riding in the passenger seat. Both the driver and the passenger of the vehicle may use the display device 100.

Only a part of the display device 100 illustrated in FIG. 1 may be illustrated. The display device 100 illustrated in FIG. 1 may represent a display panel among various configurations included in the display device 100. Specifically, for example, the display device 100 illustrated in FIG. 1 may represent at least a part of a display area and a non-display area of a display panel. Among the configurations of the display device 100, configurations other than those illustrated in FIG. 1 may be mounted inside (or at least a portion) of the vehicle.

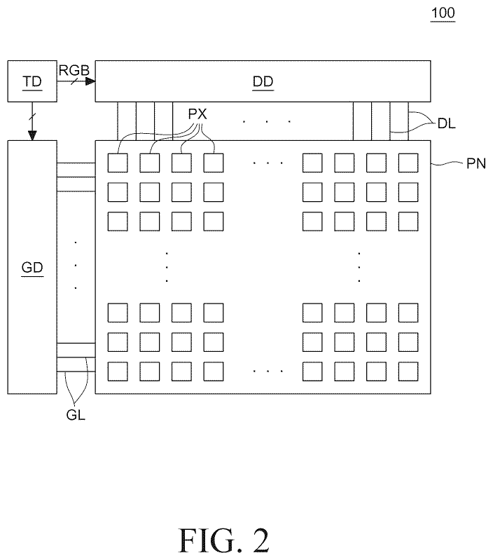

FIG. 2 is a functional block diagram of a display device according to an example implementation of the present disclosure.

An electroluminescent display device may be applied to a display device according to an example implementation of the present disclosure. The electroluminescent display device may be an organic light emitting diode display device, a quantum-dot light emitting diode display device, or an inorganic light emitting diode display device.

Referring to FIG. 2, the display device 100 may include a display panel PN, a data driving circuit DD, a gate driving circuit GD, and a timing controller TD.

The display panel PN may generate an image to be provided to the user. For example, the display panel PN may generate and display an image to be provided to the user through a plurality of pixels PX in which pixel circuits are disposed.

The data driving circuit DD, the gate driving circuit GD, and the timing controller TD may provide signals for the operation of each pixel PX through signal lines. For example, the signal lines for providing the signals for the operation of each pixel PX may include a plurality of data lines DL and a plurality of gate lines GL.

The plurality of data lines DL may include a plurality of lines arranged in a column direction and connected to pixels PX arranged in one column direction, and the plurality of gate lines GL may include a plurality of lines arranged in a row direction and connected to pixels PX arranged in one row direction.

For example, the data driving circuit DD may apply a data signal to each pixel PX through a plurality of data lines DL, the gate driving circuit GD may apply a gate signal to each pixel PX through a plurality of gate lines GL, and the power unit may supply a power voltage to each pixel PX through a power voltage supply line.

The timing controller TD may control the data driving circuit DD and the gate driving circuit GD. For example, the timing controller TD may rearrange digital video data input from the outside to match the resolution of the display panel PN and supply the rearranged digital video data RGB to the data driving circuit DD.

The data driving circuit DD may convert digital video data input from the timing controller TD into an analog data voltage based on a data control signal and supply the analog data voltage to the plurality of data lines DL.

The gate driving circuit GD may generate a scan signal and an emission signal based on the gate control signal. For example, the gate driving circuit GD may include a scan driver and an emission signal driver. The scan driver generates a scan signal in a row sequential manner to drive at least one scan line connected to each pixel row and may supply the scan signal to the scan lines. The emission signal driver generates an emission signal in a row sequential manner to drive at least one emission signal line connected to each pixel row and may supply the emission signal to the emission signal lines.

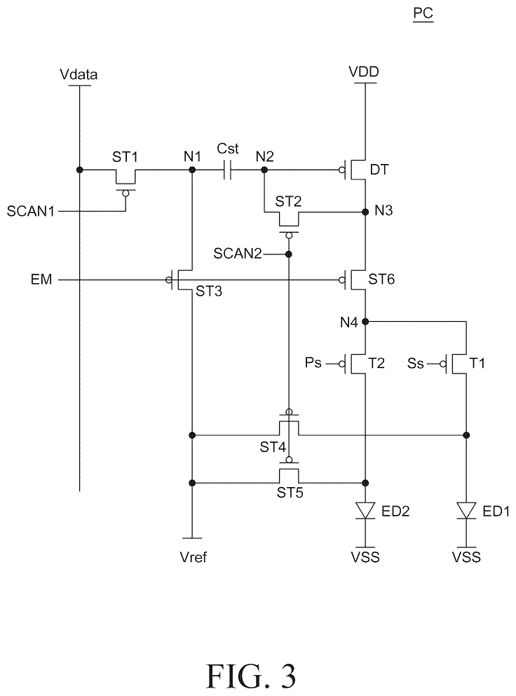

FIG. 3 is a circuit diagram illustrating an example of a display device according to an example implementation of the present disclosure.

The pixel circuit PC illustrated in FIG. 3 represents an implementation of a pixel circuit corresponding to each of the plurality of pixels PX included in the display device 100 described with reference to FIG. 2.

Referring to FIG. 3, at least some of a plurality of transistors included in the pixel circuit PC may be n-type transistors or p-type transistors. In the case of the p-type transistor, a low-level voltage of each driving signal may mean a voltage that turns on the TFT, and a high-level voltage of each driving signal may mean a voltage that turns off the TFTs.

Here, the low level voltage may correspond to a predetermined voltage lower than the high level. For example, the low level voltage may include a voltage corresponding to a range of −8 V to −12 V. The high level voltage may correspond to a predetermined voltage higher than the low level voltage. For example, the high level voltage may include a voltage corresponding to a range of 12 V to 16 V. According to an implementation, the low level voltage may be referred to as a first voltage, and the high level voltage may be referred to as a second voltage. In this case, the first voltage may be lower than the second voltage.

The pixel circuit PC may include a driving transistor DT, a plurality of switching transistors ST1 to ST6, a first transistor T1, a second transistor T2, a storage capacitor Cst, and a plurality of light emitting elements ED1 and ED2.

The driving transistor DT may control a driving current applied to the plurality of light emitting elements ED1 and ED2 according to a source-gate voltage. The driving transistor DT may include a source electrode connected to a high potential power line which supplies a high potential power voltage VDD, a gate electrode connected to a second node N2, and a drain electrode connected to a third node N3.

The first switching transistor ST1 may apply a data voltage Vdata from the data line DL to the first node N1. The first switching transistor ST1 may include a source electrode connected to the data line DL, a drain electrode connected to the first node N1, and a gate electrode connected to a first scan signal line to which a first scan signal SCAN1 is applied. The first switching transistor ST1 may be turned on or off by the first scan signal SCAN1. Accordingly, the first switching transistor ST1 may apply the data voltage Vdata from the data line DL to the first node N1 in response to the first scan signal SCAN1 at a low level, which is a turn-on level.

The second switching transistor ST2 may diode-connect the gate electrode and the drain electrode of the driving transistor DT. The second switching transistor ST2 may include a drain electrode connected to the second node N2, a source electrode connected to the third node N3, and a gate electrode connected to a second scan signal line to which a second scan signal SCAN2 is applied. The second switching transistor ST2 may be turned on or off by the second scan signal SCAN2. Accordingly, the second switching transistor ST2 may diode-connect the gate electrode and the drain electrode of the driving transistor DT in response to the second scan signal SCAN2 at a low level, which is a turn-on level.

The third switching transistor ST3 may apply the reference voltage Vref to the first node N1. The third switching transistor ST3 may include a source electrode connected to a reference voltage line which supplies a reference voltage Vref, a drain electrode connected to the first node N1, and a gate electrode connected to an emission signal line to which an emission signal EM is applied. The third switching transistor ST3 may be turned on or off by the emission signal EM. Accordingly, the third switching transistor ST3 may transmit the reference voltage Vref to the first node N1 in response to the emission signal EM at a low level, which is the turn-on level.

The fourth switching transistor ST4 may apply the reference voltage Vref to the anode electrode of the first light emitting element ED1. The fourth switching transistor ST4 may include a source electrode connected to a reference voltage line which supplies a reference voltage Vref, a drain electrode connected to an anode electrode of the first light emitting element ED1, and a gate electrode connected to a second scan signal line to which a second scan signal SCAN2 is applied. The fourth switching transistor ST4 may be turned on or off by the second scan signal SCAN2. Accordingly, the fourth switching transistor ST4 may apply the reference voltage Vref to the anode electrode of the first light emitting element ED1 in response to the second scan signal SCAN2 at a low level, which is a turn-on level.

The fifth switching transistor ST5 may apply the reference voltage Vref to the anode electrode of the second light emitting element ED2. The fifth switching transistor ST5 may include a source electrode connected to a reference voltage line which supplies a reference voltage Vref, a drain electrode connected to an anode electrode of the second light emitting element ED2, and a gate electrode connected to a second scan signal line to which a second scan signal SCAN2 is applied. The fifth switching transistor ST5 may be turned on or off by the second scan signal SCAN2. Accordingly, the fifth switching transistor ST5 may apply the reference voltage Vref to the anode electrode of the second light emitting element ED2 in response to the second scan signal SCAN2 at a low level, which is a turn-on level.

The sixth switching transistor ST6 may form a current path between the driving transistor DT and any one of the plurality of light emitting elements ED1 and ED2. The sixth switching transistor ST6 may include a source electrode connected to the third node N3, a drain electrode connected to the fourth node N4, and a gate electrode connected to a light emission signal line to which the light emission signal EM is applied. The sixth switching transistor ST6 may be turned on or off by the emission signal EM. Accordingly, the sixth switching transistor ST6 may electrically connect the third node N3 and the fourth node N4 in response to the emission signal EM at a low level, which is the turn-on level to form a current path between the driving transistor DT and any one of the plurality of light emitting elements ED1 and ED2.

The storage capacitor Cst may include a first electrode connected to the first node N1 and a second electrode connected to the second node N2. One electrode of the storage capacitor Cst may be connected to the gate electrode of the driving transistor DT, and the other electrode of the storage capacitor Cst may be connected to the first switching transistor ST1. The storage capacitor Cst may store a predetermined voltage to maintain a constant voltage of the gate electrode of the driving transistor DT while any one of the plurality of light emitting elements ED1 and ED2 emits light.

The first transistor T1 may generate a current path of the first driving current passing through the first light emitting element ED1, and the second transistor T2 may generate a current path of the second driving current passing through the second light emitting element ED2.

The first transistor T1 may be connected between the fourth node N4 and the first light emitting element ED1, and the gate electrode of the first transistor T1 may be connected to a first mode signal line that provides a first mode signal Ss. When a pixel PX to which a pixel circuit PC is applied is driven in the first mode that is a wide viewing angle mode, the first mode signal Ss may be supplied to the gate electrode of the first transistor T1 so that the first transistor T1 may be turned on. Accordingly, a current path of the first driving current passing through the first light emitting element ED1 is formed, such that the first light emitting element ED1 may emit light. In some implementations, the first transistor T1 may also be referred to as a first light emission control transistor configured to control light emission from the first light emitting element ED1.

The second transistor T2 may be connected between the fourth node N4 and the second light emitting element ED2, and the gate electrode of the second transistor T2 may be connected to a second mode signal line that provides the second mode signal Ps. When a pixel PX to which a pixel circuit PC is applied is driven the second mode that is a narrow viewing angle mode, the second mode signal Ps may be supplied to the gate electrode of the second transistor T2 so that the second transistor T2 may be turned on. Accordingly, a current path for the second driving current passing through the second light emitting element ED2 is formed, such that the second light emitting element ED2 may emit light. In some implementations, the second transistor T2 may also be referred to as a second light emission control transistor that controls the light emission of the second light emitting element ED2.

The first light emitting element ED1 may be connected between the first transistor T1, which is turned on or off by the first mode signal Ss, and a low potential power line that provides a low potential power voltage VSS. The second light emitting element ED2 may be connected between the second transistor T2, which is turned on or off by the second mode signal Ps, and the low potential power line configured to provide the low potential power voltage VSS.

In this case, the first light emitting element ED1 or the second light emitting element ED2 may be connected to another component of the pixel circuit PC, for example, the driving transistor DT by the first transistor T1 or the second transistor T2 that is turned on according to the driving mode. For example, the first light emitting element ED1 may be connected to the driving transistor DT via the first transistor T1 turned on in the first mode, and may emit light at a first viewing angle, that is, a wide viewing angle, in the first mode, which is the wide viewing angle mode by the first driving current. In addition, the second light emitting element ED2 may be connected to the driving transistor DT via the second transistor T2 turned on in the second mode, and may emit light at a second viewing angle, that is, a narrow viewing angle, in the second mode, which is the narrow viewing angle mode, by a second driving current. Here, the driving mode may be designated by a user's input or determined when a predetermined condition is satisfied.

In the first mode, only the first light emitting element ED1 may emit light, and in the second mode, only the second light emitting element ED2 may emit light. Here, in the first mode, the second mode signal Ps for controlling the emission of the second light emitting element ED2 may be output only at a high level, which is a turn-off level, so that only the first light emitting element ED1 emits light. Further, in the second mode, the first mode signal Ss for controlling the emission of the first light emitting element ED1 may be output only at a high level, which is a turn-off level, so that only the second light emitting element ED2 emits light.

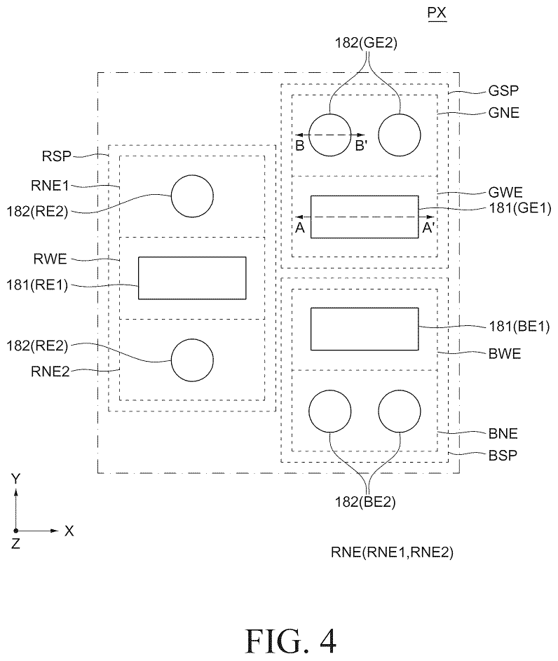

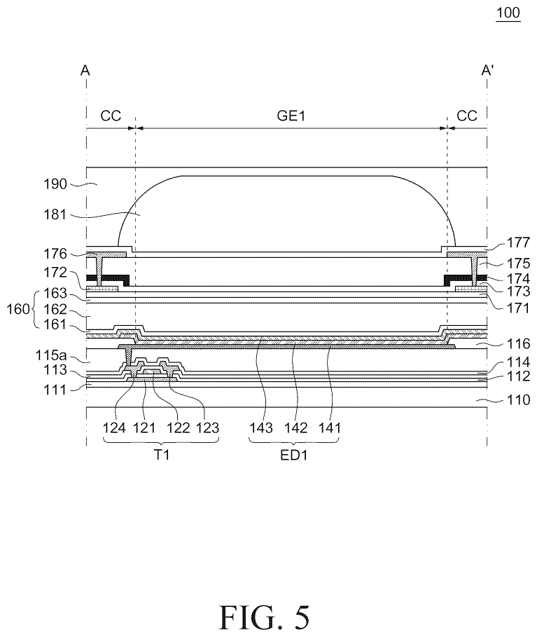

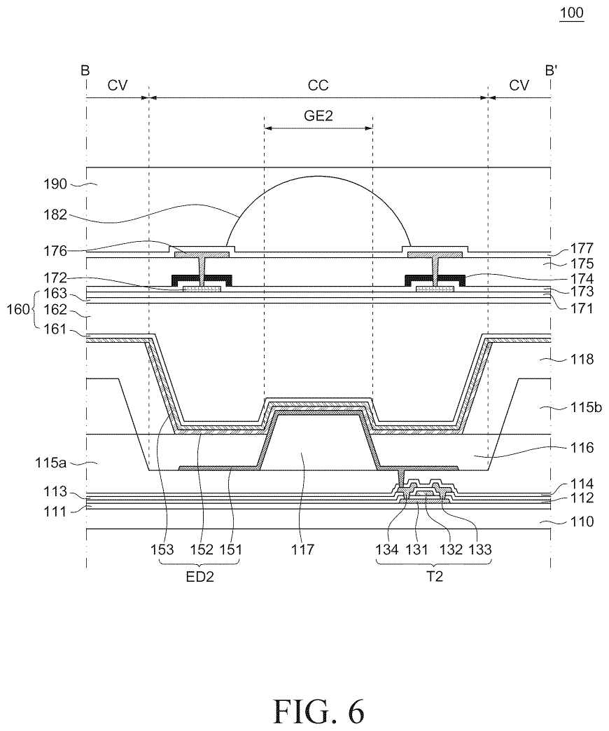

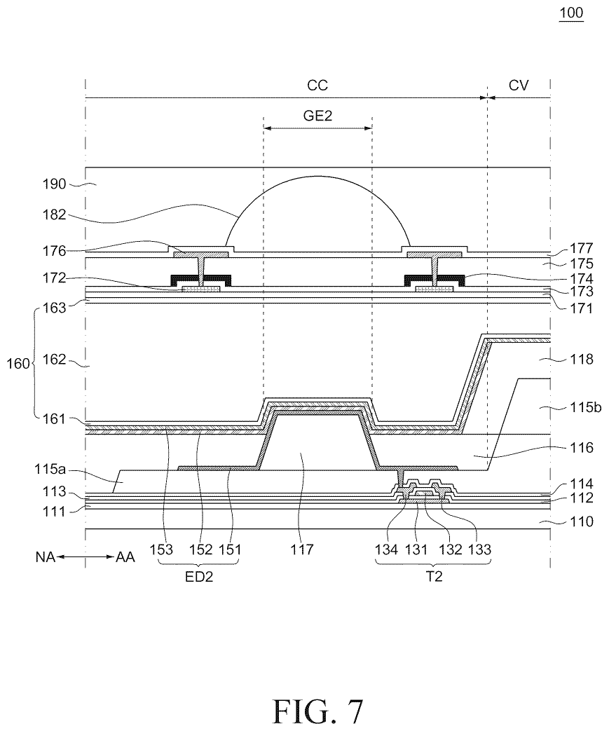

FIG. 4 is an enlarged plan view illustrating an arrangement of a display device according to an example implementation of the present disclosure. FIG. 5 is a cross-sectional view of the display device of FIG. 4 taken along line A-A′, FIG. 6 is a cross-sectional view of the display device of FIG. 4 taken along line B-B′. FIG. 7 is a cross-sectional view of a display device of FIG. 4 taken in an area adjacent to a non-display area.

FIG. 4 illustrates a plan view of a plane of the pixel PX when the pixel PX includes three sub-pixels, for example, a first sub-pixel RSP, a second sub-pixel GSP, and a third sub-pixel BSP.

In addition, FIG. 5 illustrates the pixel PX in which the first optical member 181 is disposed in the center area of the display area AA as an implementation of the display device 100 cut along the line A-A′ of FIG. 4, and FIG. 6 illustrates the pixel PX in which the second optical member 182 is disposed in the center area of the display area AA as an implementation of the display device 100 cut along the line B-B′ of FIG. 4. Further, FIG. 7 illustrates the pixel PX in which the second optical member 182 is disposed in an area adjacent to a boundary between the non-display area NA and the display area AA.

For convenience of description, FIGS. 5 to 7 illustrate only areas corresponding to the first optical area GWE and the second optical area GNE of the second sub pixel GSP, among the three sub pixels RSP, GSP, and BSP illustrated in FIG. 4, but the other sub pixels RSP, BSP may also have the same configuration.

For convenience of description, hereinafter, a horizontal direction on a plane is illustrated as a first direction X, and a vertical direction on a plane is illustrated as a second direction Y. Further, a normal direction of a plane defined by the first direction X and the second direction Y, for example, a thickness direction of the display device 100 may be defined as a third direction Z.

Referring to FIG. 4, the pixel PX may include a plurality of sub pixels RSP, GSP, and BSP representing different colors. For example, the pixel PX may include a first sub pixel RSP configured to implement red, a second sub pixel GSP configured to implement green, and a blue sub pixel BSP configured to implement blue. According to the example implementation, the first sub pixel RSP may be referred to as a red sub pixel, the second sub pixel GSP may be referred to as a green sub pixel, and the third sub pixel BSP may be referred to as a blue sub pixel. The pixel circuit PC described with reference to FIG. 3 may be disposed in each of the plurality of sub pixels RSP, GSP, and BSP included in the pixel PX.

Each of the plurality of sub pixels RSP, GSP, and BSP may include first optical areas RWE, GWE, and BWE and second optical areas RNE, GNE, and BNE that provide different viewing angles.

The first optical areas RWE, GWE, and BWE of each sub pixel RSP, GSP, and BSP may operate individually from the second optical areas RNE, GNE, and BNE of the corresponding pixel PX. For example, each sub pixel RSP, GSP, BSP may include a first light emitting element ED1 disposed in the first optical areas RWE, GWE, and BWE of the corresponding sub pixels RSP, GSP, and BSP, and a second light emitting element ED2 disposed in the second optical areas RNE, GNE, and BNE of the corresponding sub pixels RSP, GSP, and BSP.

At least some of the plurality of sub pixels RSP, GSP, and BSP may include a plurality of first optical areas RNE, GNE, and BNE. Referring to the first sub pixel RSP as an example, the first sub pixel RSP may include one first optical area RWE and a plurality of second optical areas RNE1 and RNE2. In this case, the first light optical area RWE may be disposed between the plurality of second light optical areas RNE1 and RNE2. For example, in the second direction Y, one second optical area RNE2, the first optical area RWE, and the other second optical area RNE1 may be sequentially disposed, but are not limited thereto.

In one pixel PX, the first light emitting element ED1 and the second light emitting element ED2 may be disposed in each of the first optical areas RWE, GWE, and BWE and the second optical areas RNE, GNE, and BNE of the plurality of sub pixels RSP, GSP, and BSP.

For example, in one pixel PX, a first light emitting element ED1 disposed in the first optical area RWE of the first sub pixel RSP, a second light emitting element ED2 disposed in the second optical area RNE of the first sub pixel RSP, a first light emitting element ED1 disposed in the first optical area GWE of the second sub pixel RSP, a second light emitting element ED2 disposed in the second optical area GNE of the second sub pixel GSP, a first light emitting element ED1 disposed in the first optical area BWE of the third sub pixel BSP, and a second light emitting element ED2 disposed in the second optical area BWE of the third sub pixel BSP may be disposed.

Referring to FIG. 4, at least one first optical member 181 which is disposed so as to overlap the first emission areas RE1, GE1, and BE1 of the first light emitting element ED1 may be disposed in the first optical areas RWE, GWE, and BWE of the sub pixels RSP, GSP, and BSP. At least one second optical member 182 which is disposed so as to overlap the second emission areas RE2, GE2, and BE2 of the second light emitting element ED2 may be disposed in the second optical areas RNE, GNE, and BNE of the sub pixels RSP, GSP, and BSP. In this case, the first optical areas RWE, GWE, and BWE may have a first viewing angle, and the second optical areas RNE, GNE, and BNE may have a second viewing angle smaller than the first viewing angle.

In some implementations, in each sub pixel RSP, GSP, BSP, the arrangement of the first light emitting element ED1 and the second light emitting element ED2 may be different from each other. For example, in the first sub-pixel RSP, one second light emitting element ED2, the first light emitting element ED1, and the other second light emitting element ED2 may be sequentially disposed in the second direction Y. In contrast, in the second sub-pixel GSP, the plurality of second light emitting elements ED2 may be disposed in the second optical area GNE, and one first light emitting element ED1 may be disposed in the first optical area GWE. In this case, the plurality of second light emitting elements ED2 may be disposed on the same line in the first direction X. Further, the first light emitting element ED1 and the plurality of second light emitting elements ED2 may be disposed to overlap each other in the second direction Y. In addition, in the second sub pixel GSP, the plurality of second light emitting elements ED2 may be disposed above the first light emitting element ED1. Next, in the third sub pixel BSP, the plurality of second light emitting elements ED2 may be disposed in the second optical area BNE, and one first light emitting element ED1 may be disposed in the first optical area BWE. In this case, the plurality of second light emitting elements ED2 may be disposed on the same line in the first direction X. Further, the first light emitting element ED1 and the plurality of second light emitting elements ED2 may be disposed to overlap each other in the second direction Y. Further, in the third sub pixel BSP, the plurality of second light emitting elements ED2 may be disposed below the first light emitting element ED1. However, this is only an example, and the arrangement of the first light emitting element ED1 and the second light emitting element ED2 in each sub pixel RSP, GSP, BSP is not limited thereto.

Referring to FIGS. 5 to 7 together, a display device 100 according to an example implementation of the present disclosure may include a substrate 110, a buffer film 111, a gate insulating film 112, a first interlayer insulating film 113, a lower protection film 114, a first planarization layer 115a, a second planarization layer 115b, a bank 116, an island pattern 117, a spacer 118, a first transistor T1, a second transistor T2, a first light emitting element ED1, a second light emitting element ED2, an encapsulation member 160, a touch buffer layer 171, a conductive pattern 172, a second interlayer insulating film 173, a black matrix 174, a third interlayer insulating film 175, a barrier layer 176, a fourth interlayer insulating film 177, a first optical member 181, and an optical member protection film 190.

The substrate 110 may include a display area AA and a non-display area NA. The display area AA is an area where an image is displayed, and the non-display area NA may be an area where an image is not displayed. In some implementations, the non-display area NA may be disposed along a circumference of the display area AA.

The substrate 110 may include an insulating material. The substrate 110 may include a transparent material. For example, the substrate 110 may include glass or plastic.

A buffer film 111 may be disposed on the substrate 110. The buffer film 111 may include an insulating material. For example, the buffer film 111 may include an inorganic insulating material such as silicon oxide (SiOx) and silicon nitride (SiNx). The buffer film 111 may have a multilayer structure. For example, the buffer film 111 may have a stacked structure of a film made of silicon nitride (SiNx) and a film made of silicon oxide (SiOx).

The buffer film 111 may be positioned between the substrate 110 and a driving part of each sub pixel RSP, GSP, BSP. The buffer film 111 may reduce contamination by the substrate 110 during a process of forming the driving part. For example, a top surface of the substrate 110 facing the driving part of each sub pixel RSP, GSP, BSP may be covered by the buffer film 111. The driving part of each sub pixel RSP, GSP, BSP may be located on the buffer film 111.

A gate insulating film 112 may be disposed on the buffer film 111. The gate insulating film 112 may include an insulating material. For example, the gate insulating film 112 may include an inorganic insulating material such as silicon oxide (SiO) and silicon nitride (SiN).

A first interlayer insulating film 113 may be disposed on the gate insulating film 112. The first interlayer insulating film 113 may include an insulating material. For example, the first interlayer insulating film 113 may include an inorganic insulating material such as silicon oxide (SiO) and silicon nitride (SiN). The first interlayer insulating film 113 may extend between the gate electrodes 122 and 132 and the source electrodes 123 and 133 and between the gate electrodes 122 and 132 and the drain electrodes 124 and 134 of each of the transistors T1 and T2. For example, the source electrodes 123 and 133 and the drain electrodes 124 and 134 of the first transistor T1 and the second transistor T2 may be insulated from the gate electrodes 122 and 132 by the first interlayer insulating film 113. The first interlayer insulating film 113 may cover the gate electrodes 122 and 132 of the first transistor T1 and the second transistor T2. The source electrodes 123 and 133 and the drain electrodes 124 and 134 of each sub pixel RSP, GSP, BSP may be positioned on the first interlayer insulating film 113. The gate insulating film 112 and the first interlayer insulating film 113 may expose a source region and a drain region of each semiconductor layer 121 or 131 located in each sub pixel RSP, GSP, BSP.

A lower protection film 114 may be disposed on the first interlayer insulating film 113. The lower protection film 114 may include an insulating material. For example, the lower protection film 114 may include an inorganic insulating material such as silicon oxide (SiO) and silicon nitride (SiN).

The lower protection film 114 may reduce damage to the driving part due to external moisture and impact. The lower protection film 114 may extend along surfaces of the first transistor T1 and the second transistor T2. The lower protection film 114 may be in contact with the first interlayer insulating film 113 outside the driving part located in each sub pixel RSP, GSP, BSP.

In some implementations, a first transistor T1 and a second transistor T2 may be disposed on the substrate 110. The first transistor T1 may be electrically connected between the drain electrode of the driving transistor DT and a first lower electrode 141 of the first light emitting element ED1. The second transistor T2 may be electrically connected between the drain electrode of the driving transistor DT and a second lower electrode 151 of the second light emitting element ED2.

The first transistor T1 may include a first semiconductor layer 121, a first gate electrode 122, a first source electrode 123, and a first drain electrode 124. The first transistor T1 may have the same structure as the switching transistor and the driving transistor.

For example, the first semiconductor layer 121 may be positioned between the buffer film 111 and the gate insulating film 112, and the first gate electrode 122 may be positioned between the gate insulating film 112 and the first interlayer insulating film 113. The first source electrode 123 and the first drain electrode 124 may be positioned between the first interlayer insulating film 113 and the lower protection film 114. The first gate electrode 122 may overlap the channel region of the first semiconductor layer 121. The first source electrode 123 may be electrically connected to a source region of the first semiconductor layer 121. The first drain electrode 124 may be electrically connected to a drain region of the first semiconductor layer 121.

The second transistor T2 may include a second semiconductor layer 131, a second gate electrode 132, a second source electrode 133, and a second drain electrode 134. For example, the second semiconductor layer 131 may be positioned on the same layer as the first semiconductor layer 121, the second gate electrode 132 may be positioned on the same layer as the first gate electrode 122, and the second source electrode 133 and the second drain electrode 134 may be positioned on the same layer as the first source electrode 123 and the first drain electrode 124.

The first planarization layer 115a may be disposed on the lower protection film 114. The first planarization layer 115a may remove a step of each sub pixel RSP, GSP, BSP.

The first planarization layer 115a may include an insulating material. The first planarization layer 115a may include a material different from that of the lower protection film 114. For example, the first planarization layer 115a may include an organic insulating material.

Referring to FIG. 5, in the area in which the first optical member 181 is disposed, the first planarization layer 115a may be a flat surface having a flat top surface. The second planarization layer 115b may not be disposed on the first planarization layer 115a. In addition, the first planarization layer 115a may not include a convex portion CV. Instead, the first planarization layer 115a may be formed of only a concave portion CC.

Next, referring to FIG. 6, in the area in which the second optical member 182 is disposed, the first planarization layer 115a includes a convex portion CV and a concave portion CC. In this example, the convex portion CV may be disposed to surround the concave portion CC.

Referring to FIG. 7, in some pixels PX adjacent to a boundary between the display area AA and the non-display area NA, a convex portion CV of the first planarization layer 115a may not be disposed near a boundary between the display area AA and the non-display area NA, and instead, only a concave portion CC may be disposed in that region. As such, the concave portion CC may include a first portion adjacent to the convex portion CV, and a second portion adjacent to a boundary between a display area AA and a non-display area NA.

The second planarization layer 115b may be disposed on a partial area of the first planarization layer 115a. For example, referring to FIGS. 6 and 7, the second planarization layer 115b may be disposed on the convex portion CV of the first planarization layer 115a. The second planarization layer 115b may overlap the convex portion CV of the first planarization layer 115a. However, referring to FIG. 7, the second planarization layer 115b may not be disposed in an outer region of the display area AA adjacent to the boundary between the non-display area NA and the display area AA, where only the concave portion CC of the first planarization layer 115a is disposed.

The second planarization layer 115b may include an insulating material. The second planarization layer 115b may include a material different from that of the first planarization layer 115a, but is not limited thereto. For example, the second planarization layer 115b may be formed of the same material as the first planarization layer 115a. In FIGS. 5 to 7, it is illustrated that the first planarization layer 115a and the second planarization layer 115b are separate configurations, but when the second planarization layer 115b is made of the same material as the first planarization layer 115a, an interface may not exist between the first planarization layer 115a and the second planarization layer 115b. Instead, in such scenarios, the first planarization layer 115a and the second planarization layer 115b may be integrally formed.

Referring to FIGS. 6 and 7, the island pattern 117 is disposed in the concave portion CC of the first planarization layer 115a in the area in which the second optical member 182 is disposed.

The island pattern 117 may be disposed in the concave portion CC of the first planarization layer 115a and spaced apart from the convex portion CV of the adjacent first planarization layer 115a. In some implementations, the convex portion CV of the first planarization layer 115a may be disposed to surround the island pattern 117.

The height of the top surface of the island pattern 117 may be higher than a height of the convex portion CV of the first planarization layer 115a but lower than a height of the top surface of the second planarization layer 115b. The thickness of the island pattern 117 may be the same as the thickness of the second planarization layer 115b, but is not limited thereto.

The island pattern 117 may include an insulating material. The island pattern 117 may include the same material as the second planarization layer 115b. In addition, the island pattern 117 may be formed by the same process as the second planarization layer 115b, but is not limited thereto.

The first light emitting element ED1 and the second light emitting element ED2 of each sub pixel RSP, GSP, BSP are disposed on the first planarization layer 115a of the corresponding sub pixel RSP, GSP, BSP. For example, the first lower electrode 141 of the first light emitting element ED1 may be electrically connected to the first drain electrode 124 or the first source electrode 123 of the first transistor T1 through a contact hole penetrating through the lower protection film 114 and the first planarization layer 115a. Also, the second lower electrode 151 of the second light emitting element ED2 may be electrically connected to the second drain electrode 134 or the second source electrode 133 of the second transistor T2 through a contact hole penetrating through the lower protection film 114 and the first planarization layer 115a.

The first light emitting element ED1 may emit light representing a specific color. For example, the first light emitting element ED1 may include a first lower electrode 141, a first emission layer 142, and a first upper electrode 143 sequentially stacked on the substrate 110.

The first lower electrode 141 may include a conductive material. The first lower electrode 141 may include a material having high reflectivity. For example, the first lower electrode 141 may include a metal such as aluminum (Al) and silver (Ag). The first lower electrode 141 may have a multilayer structure. For example, the first lower electrode 141 may have a structure in which a reflective electrode made of metal is positioned between transparent electrodes made of a transparent conductive material such as ITO and IZO. The first lower electrode 141 may be electrically connected to the first drain electrode 124 of the first transistor T1 through a contact hole penetrating through the lower protection film 114 and the overcoat layer 115.

Referring to FIG. 5, the first lower electrode 141 of the first light emitting element ED1 may be disposed on the first planarization layer 115a with a flat top surface. Therefore, an upper surface of the first lower electrode 141 of the first light emitting element ED1 may be disposed to be flat. The first emission layer 142 may generate light having a luminance corresponding to a voltage difference between the first lower electrode 141 and the first upper electrode 143. For example, the first emission layer 142 may include an emission material layer (EML) including a light emitting material. The light emitting material may include an organic material, an inorganic material, or a hybrid material.

The first emission layer 142 may have a multilayer structure. For example, the first emission layer 142 may further include at least one of a hole injection layer (HIL), a hole transport layer (HTL), an electron transport layer (ETL), and an electron injection layer (EIL).

The first upper electrode 143 may include a conductive material. The first upper electrode 143 may include a material different from that of the first lower electrode 141. The transmittance of the first upper electrode 143 may be higher than that of the first lower electrode 141. For example, the first upper electrode 143 may be formed of a transparent conductive material, such as indium tin oxide (ITO) or indium zinc oxide (IZO), a metal alloy, such as MgAg, or an ytterbium (Yb) alloy. Accordingly, in the display device 100 according to the example implementation of the present disclosure, light generated by the first light emitting layer 142 may be emitted through the first upper electrode 143.

The bank 116 is disposed between the first lower electrode 141 and the first emission layer 142. The bank 116 may be disposed to cover both ends of the first lower electrode 141. The bank 116 may be disposed to expose a part of the first lower electrode 141, and the exposed first lower electrode 141 may be in contact with the first emission layer 142. Therefore, the first emission area GE1 may be defined by the bank 116. The first emission area GE1 may be formed flat to correspond to the shape of the upper surface of the first lower electrode 141.

The bank 116 may be made of polyimide resin, acrylic resin, benzocyclobutene (BCB) resin, or the like, but is not limited thereto.

The second light emitting element ED2 may implement the same color as the first light emitting element ED1 disposed in the same sub pixel RSP, GSP, BSP. For example, the second light emitting element ED2 may include a second lower electrode 151, a second emission layer 152, and a second upper electrode 153 sequentially stacked on the substrate 110.

Referring to FIGS. 6 and 7, the second lower electrode 151 may be disposed on the concave portion CC and the island pattern 117 of the first planarization layer 115a. For example, the second lower electrode 151 may extend from the concave portion CC of the first planarization layer 115a along the side surface and the upper surface of the island pattern 117. As such, the second lower electrode 151 may be disposed to cover the island pattern 117. Therefore, at least a portion of the second lower electrode 151 of the second light emitting element ED2 may protrude upward. As shown in FIGS. 6 and 7, the second lower electrode 151 may include an inclined portion, which is in contact with the side surface of the island pattern 117, and a flat portion, which is in contact with the top (or upper) surface of the island pattern 117. In addition, the second lower electrode 151 may further include a flat portion, which is in contact with the first planarization layer 115a (for example, the concave portion CC of the first planarization layer 115a).

The second lower electrode 151 may include the same material as the first lower electrode 141, but is not limited thereto. The second lower electrode 151 may include a material having a high reflectance. For example, the second lower electrode 151 may include a metal such as aluminum (Al) and silver (Ag). The second lower electrode 151 may have a multilayer structure. For example, the second lower electrode 151 may have a structure in which a reflective electrode made of metal is positioned between transparent electrodes made of a transparent conductive material such as ITO and IZO. The second lower electrode 151 may be electrically connected to the second drain electrode 134 of the second transistor T2 through a contact hole passing through the lower protection film 114 and the overcoat layer 115.

The second emission layer 152 and the second upper electrode 153 may be sequentially disposed on the second lower electrode 151. The second emission layer 152 and the second upper electrode 153 may be disposed to cover an upper portion of the island pattern 117.

In some implementations, a bank 116 is disposed on the second lower electrode 151.

Referring to FIGS. 6 and 7, the bank 116 is disposed to cover both ends of the second lower electrode 151. Further, the bank 116 is disposed to surround the lower portion of the island pattern 117 in the concave portion CC of the first planarization layer 115a. The bank 116 may be disposed between the island pattern 117 and the convex portion CV of the first planarization layer 115a.

The height of the top surface of the bank 116 may be lower than the height of the top surface of the island pattern 117. Therefore, the upper portion of the island pattern 117 may be exposed by the bank 116. Accordingly, the upper portion of the second lower electrode 151 formed along the island pattern 117 may also be exposed by the bank 116. In addition, the height of the top surface of the bank 116 may be the same as the height of the top surface of the convex portion CV of the first planarization layer 115a, but is not limited thereto.

The bank 116 may be disposed between the second lower electrode 151 and the second emission layer 152. Therefore, the second emission layer 152 is in contact with the second lower electrode 151 exposed by the bank 116 to form a second emission area GE2.

The size of the first emission area GE1 of the first light emitting element ED1 may be larger than the size of the second emission area GE2 of the second light emitting element ED2, but is not limited thereto.

A spacer 118 may be disposed on the bank 116 and the second planarization layer 115b. The spacer 118 may maintain a predetermined distance between the deposition mask and the second emission area GE2 to reduce damage due to contact with the deposition mask. Accordingly, the height of the upper (or top) surface of the spacer 118 may be higher than the height of the upper (or top) surface of the island pattern 117.

The spacer 118 may be disposed to surround the second emission area GE2. The spacer 118 may be disposed to cover the second planarization layer 115b. Accordingly, at least a portion of the spacer 118 may be in contact with the upper surface of the bank 116. The spacer 118 may be spaced apart from the island pattern 117.

Referring to FIG. 7, the spacer 118 may not be disposed in an outer portion of the display area AA adjacent to a boundary between the non-display area NA and the display area AA.

The spacer 118 may be made of, for example, polyimide resin, acrylic resin, or benzocyclobutene (BCB) resin, but is not limited thereto. The spacer 118 may include a black material, but is not limited thereto.

Referring to FIGS. 6 and 7, the second emission layer 152 may be disposed to cover the second lower electrode 151 exposed by the bank 116. The second emission layer 152 may be disposed to cover upper portion of side surface and upper surface of the island pattern 117. Further, the second emission layer 152 may extend from the island pattern 117 to the side surface of the spacer 118 along the top surface of the bank 116.

The second emission layer 152 may be spaced apart from the first emission layer 142. Accordingly, light emission due to a leakage current of the display device 100 may be mitigated. Further, in the display device 100, light may be generated only in one of the first emission layer 142 and the second emission layer 152 according to a user's selection or a predetermined condition.

The second upper electrode 153 may be disposed on the second emission layer 152. The second upper electrode 153 may be electrically connected to the first upper electrode 143, For example, in the same sub pixel, a voltage applied to the second upper electrode 153 of the second light emitting element ED2 may be equal to a voltage applied to the first upper electrode 143 of the first light emitting element ED1.

The second upper electrode 153 may include the same material as the first upper electrode 143. For example, in the same sub-pixel, the second upper electrode 153 may be formed simultaneously with the first upper electrode 143. The second upper electrode 153 may extend onto the bank 116 and the spacer 118 to be in direct contact with the first upper electrode 143 located in the same sub-pixel. The luminance of the first optical area and the luminance of the second optical area located in each sub-pixel may be controlled by the driving current generated in the corresponding sub-pixel.

The encapsulation member 160 may be positioned on the first light emitting element ED1 and the second light emitting element ED2. The encapsulation member 160 may reduce damage to the first light emitting element ED1 and the second light emitting element ED2 due to moisture and impact from the outside. The encapsulation member 160 may have a multilayer structure. For example, the encapsulation member 160 may include a first encapsulation layer 161, a second encapsulation layer 162, and a third encapsulation layer 163 which are sequentially stacked, but is not limited thereto.

Each of the first encapsulation layer 161, the second encapsulation layer 162, and the third encapsulation layer 163 may include an insulating material. The second encapsulation layer 162 may include a material different from those of the first encapsulation layer 161 and the third encapsulation layer 163. For example, the first encapsulation layer 161 and the third encapsulation layer 163 may be inorganic encapsulation layers including an inorganic insulating material, and the second encapsulation layer 162 may be an organic encapsulation layer including an organic insulating material. Accordingly, damage to the first light emitting element ED1 and the second light emitting element ED2 of the display device 100 due to moisture and impact from the outside may be more effectively reduced.

A touch buffer layer 171 may be disposed on the encapsulation member 180. The touch buffer layer 171 may be disposed between the encapsulation member 160 and the conductive pattern 172 to insulate the conductive pattern 172. For example, the touch buffer layer 171 may include an insulating material. For example, the touch buffer layer 171 may be formed of an organic insulating material or an inorganic insulating material, but is not limited thereto.

The conductive pattern 172 may be disposed on the touch buffer layer 171. The conductive pattern 172 may be electrically connected to the barrier layers 176 on the second interlayer insulating film 173, but is not limited thereto. Alternatively, separately from the conductive pattern 172, a touch bridge electrode connected to touch electrodes which may be disposed on the second interlayer insulating film 173 may be further disposed. In this case, the conductive pattern 172 may be disposed on the same layer as the touch bridge electrode. Further, the conductive pattern 172 may be formed of the same material as the touch bridge electrode. For example, the conductive pattern 172 may include a metal material such as titanium (Ti), aluminum (Al), silver (Ag), copper (Cu), and a magnesium-silver alloy (Mg:Ag), but is not limited thereto.

A second interlayer insulating film 173 may be disposed on the conductive pattern 172. The second interlayer insulating film 173 may be disposed between the conductive pattern 172 and the black matrix 174 to insulate the conductive pattern 172. The second interlayer insulating film 173 may include an insulating material. For example, the second interlayer insulating film 173 may include an organic insulating material or an inorganic insulating material, but is not limited thereto.

A black matrix 174 may be disposed on the second interlayer insulating film 173. The black matrix 174 may be disposed between the plurality of sub-pixels to reduce color mixture of the plurality of sub-pixels. Accordingly, the black matrix 174 may be disposed to overlap the bank 116.

A third interlayer insulating film 175 may be disposed on the black matrix 174. The third interlayer insulating film 175 may include an insulating material. For example, the third interlayer insulating film 175 may include an organic insulating material or an inorganic insulating material, but is not limited thereto.

A plurality of barrier layers 176 may be positioned on the third interlayer insulating film 175. The plurality of barrier layers 176 may be disposed above the first light emitting element ED1 and the second light emitting element ED2 in the display area AA. A plurality of barrier layers 176 may be disposed on the third interlayer insulating film 175 to be spaced apart from each other. The barrier layer 176 may be disposed to overlap the bank 116 and the black matrix 174.

The barrier layer 176 may include an opaque metal material. Accordingly, the barrier layer 176 may limit the path of light generated by the first light emitting element ED1 and the second light emitting element ED2. For example, the barrier layer 176 may block light traveling in the lateral direction, among light emitted from the first emission area GE1 and the second emission area GE2. That is, the barrier layer 176, together with the first optical member 181 and the second optical member 182, may block light which travels in the lateral direction among the light emitted from the first optical areas RWE, GWE, and BWE and the light emitted from the second optical areas RNE, GNE, and BNE located in each sub-pixel.

The barrier layer 176 may include, for example, a metal material such as titanium (Ti), aluminum (Al), silver (Ag), copper (Cu), and a magnesium-silver alloy (Mg:Ag), but is not limited thereto.

A touch electrode may be further disposed on the third interlayer insulating film 175. The touch electrode may be configured to sense an external touch input using a user's finger or a touch pen.

The barrier layer 176 may be disposed on the same layer as the touch electrode. Further, the barrier layer 176 may be formed of the same material as the touch electrode, but is not limited thereto.

A fourth interlayer insulating film 177 may be disposed on the plurality of barrier layers 176 and the third interlayer insulating film 175. The fourth interlayer insulating film 177 may be disposed between the barrier layer 176 and the first optical member 181 and configured to insulate the barrier layer 176.

The first optical member 181 and the second optical member 182 are disposed on the fourth interlayer insulating film 177. In this case, the second optical member 182 is disposed to overlap the island pattern 117.

The first optical member 181 and the second optical member 182 may be disposed on the same layer as the plurality of barrier layers 176 on the third interlayer insulating film 175. For example, each of the first optical member 181 and the second optical member 182 may be disposed to cover edges of the plurality of barrier layers 176. Accordingly, ends of the first optical member 181 and the second optical member 182 may be disposed on the plurality of barrier layers 176.

In this case, the center of the first optical member 181 may coincide with the center of the first emission area GE1. In addition, the center of the second optical member 182 may coincide with the center of the second emission area GE2, but is not limited thereto.

First, referring to FIGS. 4 and 5, the first optical member 181 is disposed on the first light emitting element ED1. Light generated by the first light emitting element ED1 may be emitted through the first optical member 181.

The first optical member 181 has a shape that does not limit light from traveling in at least one direction. A planar shape of the first optical member 181 may be a shape extending in the first direction X. For example, a planar shape of the first optical member 181 may have a bar shape extending in the first direction X. Accordingly, the planar shape of the first optical member 181 may include a long side extending in the first direction X and a short side extending in the second direction Y at both ends of the long side. For example, the planar shape of the first optical member 181 may be a rectangular shape in which a long side is placed in the first direction X.

In this case, a traveling direction of light emitted from the first emission area GE1 may not be limited to the first direction X. For example, the content (or images) provided through the first optical area GWE may be shared with users arranged side by side in the first direction X. Accordingly, the content provided by the light emitted through the first optical member 181 may be provided at a wider viewing angle in the first direction X than the content provided by the light emitted through the second optical member 182. For example, the content provided by the light emitted through the first optical member 181 may be provided in a wide viewing angle mode (or share mode). The three-dimensional shape of the first optical member 181 may be a half-cylinder shape. Accordingly, at least a part of the top surface having a cross-sectional shape in which the first optical member 181 is cut in the first direction X may be flat. In addition, both side surfaces of the first optical member 181 may be formed in a curved or straight line. For example, referring to FIG. 5, a cross-sectional shape based on a long side of the first optical member 181 may be formed by an upper flat surface and a curved line extending from both ends of the flat surface toward the third interlayer insulating film 175. Alternatively, for example, the cross-sectional shape based on the long side of the first optical member 181 may be formed of an upper flat surface and a straight line vertically extending from both ends of the flat surface toward the third interlayer insulating film 119.

Next, referring to FIGS. 6 and 7, the second optical member 182 is disposed on the second light emitting element ED2. The light generated by the second light emitting element ED2 may be refracted and emitted through the second optical member 182. The second optical member 182 may restrict the propagation of the light passing through the second optical member 182 in the first direction X. For example, a planar shape of the second optical member 182 may have a circular shape. However, the present disclosure is not limited thereto, and the planar shape of the second optical member 182 may have a polygonal shape.

In this case, the light emitted from the second light emitting element ED2 may be restricted from traveling in the first direction X. For example, the content (or images) provided by the second optical area GNE may not be shared with users arranged side by side in the first direction X. Accordingly, the content provided by the light emitted through the second optical member 182 may be provided at a viewing angle narrower in the left and right than the content provided by the light emitted through the first optical member 181. For example, the content provided by the light emitted through the second optical member 182 may be provided in a narrow viewing angle mode (or private mode).

The second optical member 182 may have a hemispherical shape in a three-dimensional shape. Therefore, a cross-sectional shape in which the second optical member 182 is cut in the first direction X may be a semicircular shape, but is not limited thereto.

A planar shape of the first emission area GE1 may correspond to a shape of the first optical member 181. For example, the planar shape of the first emission area GE1 may have a bar shape extending in the first direction X. The first optical member 181 may have a larger size than the first emission area GE1. Accordingly, the efficiency of light emitted from the first emission area GE1 may be improved.

The second emission area GE2 may have a shape corresponding to the second optical member 182. For example, the planar shape of the second emission area GE2 may have a circular or polygonal shape. The second optical member 182 may have a larger size than the second emission area GE2. Accordingly, the efficiency of light emitted from the second emission area GE2 may be improved.

In some implementations, the number of second emission areas GE2 may be different for each second optical area GNE. For example, the number of second emission areas GE2 defined in the second optical area GNE of the second sub pixel GSP and the number of second emission areas BE2 defined in the second optical area BNE of the third sub pixel BSP may be larger than the number of second emission areas RE2 defined in each second optical area RNE of the first sub pixel RSP. In this case, the efficiency deviation of the second light emitting elements ED2 respectively located on the second optical areas RNE1, RNE2, GNE, and BNE may be compensated by the number of second emission areas RE2, GE2, and BE2 defined in the second optical areas RNE1, RNE2, GNE, and BNE of the sub pixels RSP, GSP, and BSP.

The optical member protection film 190 may be positioned on the first optical member 181 and the second optical member 182. The optical member protection film 190 may include an insulating material. For example, the optical member protection film 190 may include an organic insulating material.

In some implementations, among various components of the display device, a component element made of an organic material may cause out-gassing due to photolysis of the organic material when exposed to UV for a long time. For example, the organic insulating film disposed below the light emitting element may be made of an organic insulating material such as polyimide or acrylic resin. In this case, the polyimide or acrylic resin may generate a partially negatively charged gas such as NMP (N-Methyl-2-Pyrrolone) or Hexansitrile by UV. In this way, the negatively charged out-gassing component may react with a positively charged compound in the emission layer. For example, the gas compound may react with a positively charged compound constituting the hole injection layer of the emission layer. Therefore, when such an out-gassing component diffuses into the emission layer, the performance of the emission layer may deteriorate. In addition, as the emission layer deteriorates, the emission area decreases, and luminance may decrease at an outer region of the emission area. As described above, when the luminance decreases at the outer periphery of the emission area, the afterimage may be visually recognized due to the luminance difference between the light emitting element which is not degraded and the light emitting element which is degraded at other peripheral viewing angles other than the front viewing angle of the display device. As described above, a defect in which the light emitting layer is degraded or contracted may occur, thereby reducing the lifespan of the display device. At this time, when the size of the emission area is relatively small, the luminance decreases at the outer portion of the emission area due to the contraction of the emission layer due to deterioration may be more pronounced.

Accordingly, in the display device 100 according to the example implementation of the present disclosure, the island pattern 117 is formed on the first planarization layer 115a at a position overlapping the second emission area GE2 having a relatively small size. As described above, the second emission area GE2 may be disposed on the island pattern 117 to form the second emission area GE2 in a protruding shape. As described above, the second emission area GE2 is formed to protrude upward, so that the length of the second emission area GE2 itself may be longer than when formed to be flat. Further, the second light emitting element ED2 is disposed on the island pattern 117 so that the second emission area GE2 extends to the side surface of the island pattern 117 so that a portion of the second light emitting element ED2 disposed on the side surface of the island pattern 117 may serve as a degradation buffer. Therefore, even though the second light emitting area GE2 is reduced due to deterioration from the end of the second light emitting element ED2, it is possible to reduce deterioration in luminance at the outer portion of the second light emitting area GE2. In addition, it is possible to reduce an afterimage from occurring at a peripheral viewing angle other than the front viewing angle (0°) due to a difference in luminance before and after deterioration of the second light emitting element ED2 that occurs while the second emission area RE2 is reduced.

Further, in the display device 100 according to the example implementation of the present disclosure, a portion of the second light emitting element ED2 disposed to extend to the side surface of the island pattern 117 serves as a deterioration buffer. Therefore, it is possible to suppress the deterioration of the cutoff (cut-off) performance at the peripheral viewing angle other than the front viewing angle (0°) due to the deterioration of the second light emitting element ED2.

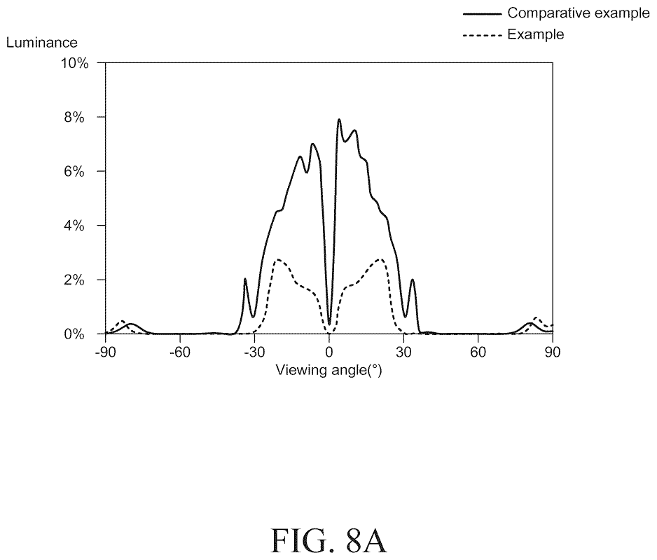

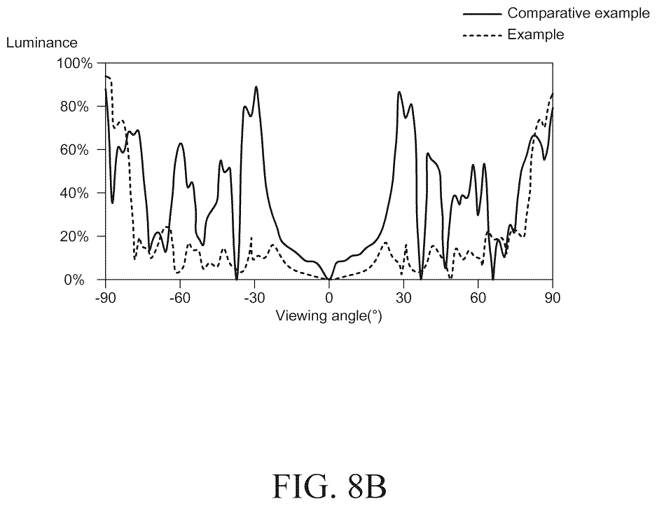

This will be described in more detail with reference to FIGS. 8A and 8B.

FIG. 8A is a result of simulating a difference in luminance before and after deterioration of a light emitting element in a comparative example and an example. FIG. 8B is a simulation result showing a ratio of a difference in luminance before and after deterioration of a light emitting element in a comparative example and an example.

In FIGS. 8A and 8B, the example is a display device 100 according to an example implementation of the present disclosure described with reference to FIGS. 1 to 7, in which the island pattern 117 protrudes about 1.0 μm from the bank 116. In the comparative example, the island pattern 117 and the second planarization layer 115b are removed compared to the example, and the second light emitting element ED2 is formed in a flat shape like the first light emitting element ED1.

The deterioration of the light emitting element in the comparative example and the example means that the light emitting element according to the comparative example and the example emits light at 65° C. for 1500 hours. In the comparative example and the example, the non-deterioration of the light emitting element means an initial state before proceeding with the deterioration process.

In FIGS. 8A and 8B, the X-axis denotes a viewing angle.

In FIG. 8A, the Y-axis represents a difference between a luminance value before deterioration and a luminance value after deterioration in each of comparative example and the example. Specifically, before the deterioration process was performed in the comparative example and the example, the luminance value according to the viewing angle (hereinafter, referred to as “non-deterioration”) was measured. At this time, when the front viewing angle, that is, the viewing angle is 0°, the luminance value according to the entire viewing angle is calculated as % by using 100% as the luminance value. In addition, the luminance value (hereinafter, referred to as “deterioration”) according to the entire viewing angle after the light emitting element is deteriorated was measured. Similarly, at this time, the luminance value of the front viewing angle with a viewing angle of 0° was used as 100%, and the luminance value according to the entire viewing angle was calculated as %. In each of the comparative example and example calculated as described above, the difference value obtained by subtracting the luminance value according to the viewing angle after the LED is deteriorated from the luminance value according to the viewing angle before deterioration and is illustrated in FIG. 8A. That is, the Y-axis of FIG. 8A refers to a difference obtained by subtracting the degradation (%) value from the non-deterioration (%) value.

Further, in FIG. 8B, the Y-axis is a result obtained by dividing a result value obtained by subtracting the degradation (%) value from the non-deterioration (%) value in each of the comparative example and the example by the non-deterioration (%) value.

First, referring to FIG. 8A, in the case of the comparative example, it was confirmed that the difference between the luminance value before the light emitting element was deteriorated and the luminance value after the light emitting element was deteriorated at the peripheral viewing angle other than the front viewing angle (0°) was larger than that of the example. Specifically, it was confirmed that, except for the front viewing angle of 0°, the difference in luminance values before and after deterioration of the light emitting element in the example was significantly reduced compared to the comparative example at peripheral viewing angles of about +30° or −30°. Through this, in the case of the comparative example in which the emission area is flat, it was confirmed that the luminance decrease occurred significantly at the peripheral viewing angle according to the reduction of the emission area. On the other hand, in the case of the example in which the emission area protrudes, it was confirmed that the luminance decrease due to the reduction of the emission area at the peripheral viewing angle was effectively reduced compared to the comparative example in which the emission area was flat. In addition, in the case of the example, it was confirmed that the luminance at a viewing angle of about ±30° rapidly decreased compared to the comparative example. Accordingly, in the case of the example, it was confirmed that the cutoff effect at the peripheral viewing angle was significantly improved compared to the comparative example.

Next, referring to FIG. 8B, in the case of the comparative example, it was confirmed that as the emission area was reduced, a large difference in luminance occurred before and after deterioration at the peripheral viewing angle. On the other hand, in the case of the example, it was confirmed that the overall luminance difference before and after deterioration at the peripheral viewing angle was significantly reduced compared to the comparative example.

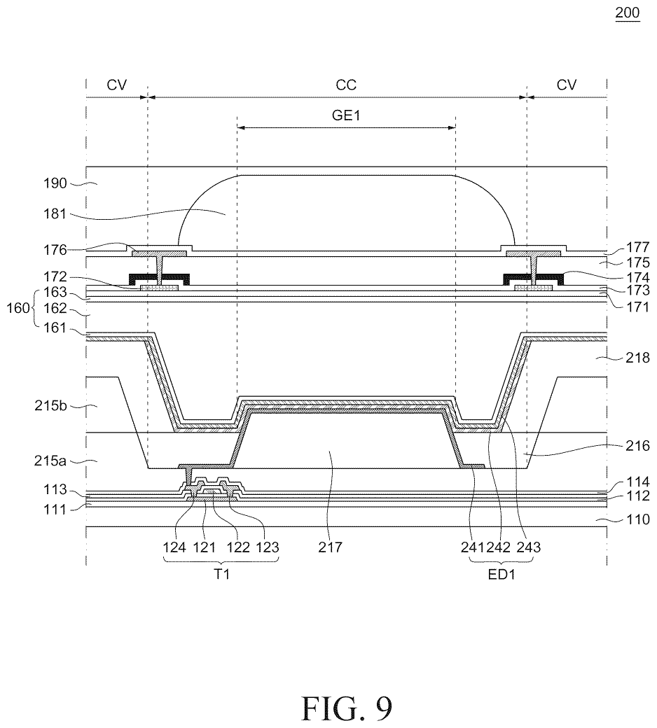

FIG. 9 is a cross-sectional view of a display device according to another example implementation of the present disclosure.

Specifically, FIG. 9 is a cross-sectional view of an area corresponding to FIG. 5. The only difference between a display device 200 of FIG. 9 and the display device 100 of FIGS. 1 to 7 is a first planarization layer 215a, a second planarization layer 215b, and an island pattern 217, but other components are substantially the same, so that a redundant description will be omitted.

Referring to FIG. 9, in another display device 200 of the present disclosure, the first planarization layer 215a may include a concave portion CC and a convex portion CV. In some implementations, the convex portion CV may be disposed to surround the concave portion CC.

The second planarization layer 215b may be disposed on a partial area of the first planarization layer 215a. The second planarization layer 215b may be disposed on the convex portion CV of the first planarization layer 215a. The second planarization layer 215b may overlap the convex portion CV of the first planarization layer 215a. However, the second planarization layer 215b may not be disposed in an outer region of the display area AA adjacent to the boundary between the non-display area NA and the display area AA.

The second planarization layer 215b may include an insulating material. The second planarization layer 215b may include a material different from that of the first planarization layer 215a, but is not limited thereto. That is, the second planarization layer 215b may be formed of the same material as the first planarization layer 215a. FIG. 9 illustrates that the first planarization layer 215a and the second planarization layer 215b are separate configurations, but when the second planarization layer 215b is made of the same material as the first planarization layer 215a, an interface may not exist between the first planarization layer 215a and the second planarization layer 215b. The first planarization layer 215a and the second planarization layer 215b may be integrally formed.

An island pattern 217 may be disposed in the concave portion CC of the first planarization layer 215a.

The island pattern 217 may be disposed in the concave portion CC of the first planarization layer 215a and spaced apart from the convex portion CV of the adjacent first planarization layer 215a. Therefore, the convex portion CV of the first planarization layer 215a may be disposed to surround the island pattern 217.

The height of the top surface of the island pattern 217 may be higher than the convex portion CV of the first planarization layer 215a. In contrast, a height of the top surface of the island pattern 217 may be lower than a height of the top surface of the second planarization layer 215b. The thickness of the island pattern 217 may be the same as the thickness of the second planarization layer 215b, but is not limited thereto.

The island pattern 217 may include an insulating material. The island pattern 217 may include the same material as the second planarization layer 215b. In addition, the island pattern 217 may be formed by the same process as the second planarization layer 215b, but is not limited thereto.

The first light emitting element ED1 may be disposed on the island pattern 217. The first light emitting element ED1 may include a first lower electrode 241, a first emission layer 242, and a first upper electrode 243 sequentially stacked on the island pattern 217.

The common configurations of the first lower electrode 241, the first emission layer 242, and the first upper electrode 243 are the same as those of the first lower electrode 141, the first emission layer 142, and the first upper electrode 143 of the display device 100 of FIG. 5, and therefore, redundant descriptions thereof will be omitted.

Referring to FIG. 9, the first lower electrode 241 may be disposed on the concave portion CC and the island pattern 217 of the first planarization layer 215a. For example, the first lower electrode 241 may extend from the concave portion CC of the first planarization layer 215a along the side surface and the upper surface of the island pattern 217. As such, the first lower electrode 241 may be disposed to cover the island pattern 217. Therefore, at least a part of the first lower electrode 241 of the first light emitting element ED1 may protrude upward.

The first emission layer 242 and the first upper electrode 243 may be sequentially disposed on the first lower electrode 241. The first emission layer 242 and the first upper electrode 243 may be disposed to cover an upper portion of the island pattern 217.

The bank 216 may be disposed on the first lower electrode 241.

The bank 216 may be disposed to cover both ends of the first lower electrode 241. In addition, the bank 216 may be disposed to surround the lower portion of the island pattern 217 in the concave portion CC of the first planarization layer 215a. The bank 216 may be disposed between the island pattern 217 and the convex portion CV of the first planarization layer 215a.

The height of the upper surface of the bank 216 may be lower than the height of the upper surface of the island pattern 217. Accordingly, the upper portion of the island pattern 217 may be exposed by the bank 216. Accordingly, the upper portion of the first lower electrode 241 formed along the island pattern 217 may also be exposed by the bank 216. In addition, the height of the top surface of the bank 216 may be the same as the height of the top surface of the convex portion CV of the first planarization layer 215a, but is not limited thereto.

The bank 216 may be disposed between the first lower electrode 241 and the first emission layer 242. Therefore, the first emission layer 242 is in contact with the first lower electrode 241 exposed by the bank 216 to form the first emission area GE1.

The size of the first emission area GE1 of the first light emitting element ED1 may be larger than the size of the second emission area GE2 of the second light emitting element ED2, but is not limited thereto.

A spacer 218 may be disposed on the bank 216 and the second planarization layer 215b. The spacer 218 maintains a predetermined distance between the deposition mask and the first emission area GE1 to reduce damage due to contact with the deposition mask. Accordingly, the height of the upper surface of the spacer 218 may be higher than the height of the upper surface of the island pattern 217.

The spacer 218 may be disposed to surround the first emission area GE1. The spacer 218 may be disposed to cover the second planarization layer 215b. Accordingly, at least a portion of the spacer 218 may be in contact with the top surface of the bank 216. The spacer 218 may be spaced apart from the island pattern 217.

In some implementations, a spacer 218 may not be disposed at an outer portion of the display area AA adjacent to a boundary between the non-display area NA and the display area AA.

The spacer 218 may be formed of, for example, polyimide resin, acrylic resin, or benzocyclobutene (BCB) resin, but is not limited thereto. The spacer 218 may include a black material, but is not limited thereto.

The first emission layer 242 may be disposed to cover the first lower electrode 241 exposed by the bank 216. The first emission layer 242 may be disposed to cover upper side (or upper portion of side surface) and upper surfaces of the island pattern 217. Further, the first emission layer 242 may extend from the island pattern 217 to the side surface of the spacer 218 along the top surface of the bank 216.

In the display device 200 according to another example implementation of the present disclosure, the island pattern 217 may be formed on the first planarization layer 215a even at a position overlapping the first emission area GE1. As described above, the first emission area GE1 is disposed on the island pattern 217 to form the first emission area GE1 in a protruding shape. In this way, the first emission area GE1 is formed to protrude upward, so that the length of the first emission area GE1 may be longer than when formed to be flat, and the end of the extended first light emitting element ED1 may serve as a deterioration buffer. Therefore, even though the first light emitting area GE1 is reduced due to deterioration from the end of the first light emitting element ED1, it is possible to reduce deterioration in luminance at the outer portion of the first light emitting area GE1. In addition, it is possible to reduce an afterimage from occurring at a peripheral viewing angle other than the front viewing angle (0°) due to a difference in luminance before and after deterioration of the first light emitting element ED1 generated while the first emission area RE1 is reduced.

The example implementations of the present disclosure can also be described as follows:

A display device according to an example implementation of the present disclosure includes: a substrate; a first planarization layer disposed on the substrate and including a convex portion and a concave portion; an island pattern disposed on the concave portion of the first planarization layer; a light emitting element comprising a lower electrode disposed on a side surface and an upper (or top) surface of the island pattern, a light emitting layer disposed on the lower electrode, and an upper electrode disposed on the light emitting layer; a bank disposed between the lower electrode and the light emitting layer on the first planarization layer and disposed to surround a lower portion of the island pattern; and an optical member disposed on the light emitting element and disposed to overlap the island pattern.

The optical member may include a first optical member having a planar shape of a bar shape and a three-dimensional shape of a half cylinder shape, and the island pattern may overlap the first optical member.

The optical member may further include a second optical member having a planar shape of a circular shape and three-dimensional shape of a hemispherical shape, and the island pattern may overlap the second optical member.

The bank may be disposed between the island pattern and the convex portion.

The display device may further include a second planarization layer disposed on the convex portion of the first planarization layer, and a spacer disposed to cover the second planarization layer, and the second planarization layer may be formed of the same material as the island pattern.

The height of top upper surface of the spacer may be higher than the height of the top surface of the island pattern.

The height of the top surface of the island pattern may be higher than the height of the top surface of the convex portion.

The first optical member may overlap a first light emitting element in the light emitting element, and the second optical member may overlap a second light emitting element in the light emitting element, and the second light emitting element may implement the same color as the first light emitting element disposed in the same sub pixel.

A height of a top surface of the island pattern may be lower than a height of a top surface of the second planarization layer.

A height of a top surface of the bank may be lower than a height of a top surface of the island pattern.

The lower electrode may include a inclined portion, which is in contact with the side surface of the island pattern, and a flat portion, which is in contact with the top surface of the island pattern.

The emission layer may extend from the island pattern to a side surface of the spacer along a top surface of the bank.

The concave portion may include a first portion adjacent to the convex portion, and a second portion adjacent to a boundary between a display area and a non-display area.

A display device according to another example implementation of the present disclosure includes a substrate, a first planarization layer disposed on the substrate, a first island pattern disposed on the first planarization layer, a plurality of first light emitting elements including a first emission area disposed on an upper (or top) surface and a side surface of the first island pattern, and a circular first optical member overlapping the first emission area.

The display device may further include a second island pattern disposed on the first planarization layer and spaced apart from the first island pattern, a plurality of second light emitting elements including a second emission area disposed on an upper (or top) surface and a side surface of the second island pattern, and a bar-shaped second optical member which overlaps the second emission area.

The plurality of first light emitting elements may include a first lower electrode, a light emitting layer, and a first upper electrode, and the display device may further include a bank configured to surround a lower portion of the first island pattern between the first lower electrode and the light emitting layer.

The first planarization layer may include a convex portion and a concave portion, and the first island pattern may be disposed in the concave portion.

The height of the top surface of the first island pattern may be higher than the height of the convex portion of the first planarization layer.

The display device may further include a spacer disposed on the convex portion, and a height of a top surface of the first island pattern may be lower than a height of the spacer.

The display device may further include a second planarization layer disposed on the convex portion, the second planarization layer may include the same material as the first island pattern, and the second planarization layer and the second island pattern may have the same thickness.

Although the example implementations of the present disclosure have been described in detail with reference to the accompanying drawings, the present disclosure is not limited thereto and may be embodied in various forms without departing from the technical concept of the present disclosure. Therefore, the example implementations of the present disclosure are provided for illustrative purposes only but not intended to limit the technical concept of the present disclosure. The scope of the technical concept of the present disclosure is not limited thereto. Therefore, it should be understood that the above-described implementations are illustrative in all aspects and do not limit the present disclosure. All the technical concepts in the equivalent scope of the present disclosure should be construed as falling within the scope of the present disclosure.

What is claimed is:

1. A display device, comprising:
a substrate;
a first planarization layer disposed on the substrate and including a convex portion and a concave portion;
an island pattern disposed on the concave portion of the first planarization layer;
a light emitting element comprising (i) a lower electrode disposed on a side surface of the first island pattern and on a top surface of the island pattern, (ii) a light emitting layer disposed on the lower electrode, and an (iii) upper electrode disposed on the light emitting layer,
a bank disposed, in a cross-section view, between the lower electrode and the light emitting layer on the first planarization layer and disposed, in a plan view, to surround a lower portion of the island pattern; and
an optical member disposed on the light emitting element and disposed to overlap the island pattern.

2. The display device according to claim 1, wherein the optical member includes a first optical member having a planar shape of a bar shape and having a three-dimensional shape of a half cylinder shape, and
wherein the island pattern overlaps the first optical member.

3. The display device according to claim 2, wherein the optical member further includes a second optical member having a planar shape of a circular shape and having a three-dimensional shape of a hemispherical shape, and
wherein the island pattern overlaps the second optical member.

4. The display device according to claim 1, wherein the bank is disposed between the island pattern and the convex portion of the first planarization layer, in the plan view.

5. The display device according to claim 1, further comprising:
a second planarization layer disposed on the convex portion of the first planarization layer; and
a spacer disposed to cover the second planarization layer,
wherein the second planarization layer is formed of the same material as the island pattern.

6. The display device according to claim 5, wherein a height of a top surface of the spacer is higher than a height of a top surface of the island pattern.

7. The display device according to claim 1, wherein a height of a top surface of the island pattern is higher than a height of a top surface of the convex portion of the first planarization layer.

8. The display device according to claim 3, wherein the first optical member overlaps a first light emitting element in the light emitting element, and the second optical member overlaps a second light emitting element in the light emitting element, and
wherein the second light emitting element implements the same color as the first light emitting element disposed in the same sub pixel.

9. The display device according to claim 5, wherein a height of a top surface of the island pattern is lower than a height of a top surface of the second planarization layer.

10. The display device according to claim 1, wherein a height of a top surface of the bank is lower than a height of a top surface of the island pattern.

11. The display device according to claim 1, wherein the lower electrode includes (i) an inclined portion, which is in contact with the side surface of the island pattern, and (ii) a flat portion, which is in contact with the top surface of the island pattern.

12. The display device according to claim 6, wherein the light emitting layer extends along a top surface of the bank from the island pattern to a side surface of the spacer.

13. The display device according to claim 1, wherein the concave portion of the first planarization layer includes a first portion adjacent to the convex portion, and a second portion adjacent to a boundary between a display area and a non-display area.

14. A display device, comprising:
a substrate;
a first planarization layer disposed on the substrate;
a first island pattern disposed on the first planarization layer;
a plurality of first light emitting elements including a first emission area disposed on a top surface of the first island pattern and on a side surface of the first island pattern; and
a circular first optical member overlapping the first emission area.

15. The display device according to claim 14, further comprising:
a second island pattern disposed on the first planarization layer and spaced apart from the first island pattern;
a plurality of second light emitting elements including a second light emitting area disposed on a top surface of the second island pattern and on a side surface of the second island pattern; and
a bar-shaped second optical member overlapping the second light emitting area.

16. The display device according to claim 14, wherein the plurality of first light emitting elements includes a first lower electrode, a light emitting layer, and a first upper electrode, and
wherein the display device further includes a bank configured to surround a lower portion of the first island pattern in a plan view, and disposed between the first lower electrode and the light emitting layer in a cross-section view.

17. The display device according to claim 15, wherein the first planarization layer includes a convex portion and a concave portion, and
wherein the first island pattern is disposed in the concave portion of the first planarization layer.

18. The display device according to claim 17, wherein a height of a top surface of the first island pattern is higher than a height of a convex portion of the first planarization layer.

19. The display device according to claim 17, further comprising:
a spacer disposed on the convex portion,
wherein a height of a top surface of the first island pattern is lower than a height of the spacer.

20. The display device according to claim 17, further comprising:
a second planarization layer disposed on the convex portion,
wherein the second planarization layer includes the same material as the first island pattern, and
wherein the second planarization layer and the second island pattern have the same thickness.
